(19) United States
(12) Patent Application Publication
(10) Pub. No.: US 2026/0215035 A1
(43) Pub. Date: Jul. 23, 2026

(54) DISPLAY APPARATUS HAVING A CHARGE GENERATION LAYER

(71) Applicant: LG Display Co., Ltd., Seoul (KR)

(72) Inventors: Pu Reum KIM, Paju-si (KR); Sae Mi PARK, Paju-si (KR); Hee Su BYEON, Paju-si (KR)

(73) Assignee: LG Display Co., Ltd., Seoul (KR)

(21) Appl. No.: 19/449,075

(22) Filed: Jan. 14, 2026

(30) Foreign Application Priority Data
Jan. 23, 2025 (KR) 10-2025-0010431

(51) Int. Cl. H10H 20/816; H10H 20/813; H10H 29/01; H10H 29/41

(52) U.S. Cl. CPC H10H 20/8162; H10H 20/8131; H10H 29/012; H10H 29/41

(57) ABSTRACT

A display apparatus can include a light-emitting device on an emission area of a device substrate. The light-emitting device can include a first electrode, a light-emitting unit, and a second electrode sequentially stacked on the device substrate. The light-emitting unit can include a first emission stack and a second emission stack on the first emission stack with a charge generation layer therebetween. A planarization layer can be disposed between the device substrate and the first electrode and can include a separation trench extending in a first direction outside of the emission area. The charge generation layer can be separated by the separation trench. A side surface of the charge generation layer extending in a second direction perpendicular to the first direction can be covered by the first or second emission stack. Thus, in the display apparatus, the leakage current due to the charge generation layer can be prevented or suppressed.

### CROSS-REFERENCE TO RELATED APPLICATION

This application claims the benefit of Korean Patent Application No. 10-2025-0010431, filed on Jan. 23, 2025, which is hereby incorporated by reference as if fully set forth herein.

### BACKGROUND

### Field of the Disclosure

The present disclosure relates to a display apparatus in which a light-emitting device includes a charge generation layer disposed between emission stacks.

### Discussion of the Related Art

Generally, a display apparatus provides an image to a user. For example, the display apparatus can include a light-emitting device. The light-emitting device can emit light displaying a specific color. For example, the light-emitting device can include a light-emitting unit disposed between a first electrode and a second electrode. The light-emitting unit can include emission stacks. Each of the emission stacks can generate light. For example, a charge generation layer can be disposed between the emission stacks. Thus, in the display apparatus, the image provided to the user can include various colors.

### SUMMARY

Accordingly, the present disclosure is directed to a display apparatus that substantially obviates one or more problems due to limitations and disadvantages of the related art.

An object of the present disclosure is to provide a display apparatus capable of minimizing or reducing the decrease in the quality of the image due to the leakage current.

Another object of the present disclosure is to provide a display apparatus capable of preventing or suppressing the leakage current due to the charge generation layer.

Additional advantages, objects, and features of the present disclosure will be set forth in part in the description which follows and in part will become apparent to those having ordinary skill in the art upon examination of the following or may be learned from practice of the disclosure. The objectives and other advantages of the present disclosure may be realized and attained by the structure particularly pointed out in the written description and claims hereof as well as the appended drawings.

To achieve these objects and other advantages and in accordance with the purpose of the present disclosure, as embodied and broadly described herein, a display apparatus comprises a device substrate including a first emission area, a second emission area, and a third emission area. The second emission area is disposed side by side with the first emission area in a first direction. The third emission area is disposed side by side with the first emission area in a second direction perpendicular to the first direction. A planarization layer is disposed on the device substrate. The planarization layer overlaps the first emission area, the second emission area and the third emission area. A first light-emitting device, a second light-emitting device and a third light-emitting device are disposed on the planarization layer. The first light-emitting device overlaps the first emission area. The first light-emitting device includes a first light-emitting unit disposed between a first electrode and a second electrode. The second light-emitting device overlaps the second emission area. The second light-emitting device includes a second light-emitting unit disposed between the first electrode and the second electrode. The third light-emitting device overlaps the third emission area. The third light-emitting device includes a third light-emitting unit disposed between the first electrode and the second electrode. Each of the first light-emitting unit and the second light-emitting unit has a stacked structure of a first emission stack, a first charge generation layer and a second emission stack. The planarization layer includes a separation trench disposed between the first emission area and the second emission area. The first charge generation layer is separated by the separation trench. A side surface of the first charge generation layer is covered by the second emission stack between the first emission area and the third emission area.

The second emission stack can be in contact with the side surface of the first charge generation layer extending in the first direction.

The second emission area can realize a different color from the first emission area.

The second emission stack can generate a light displaying a different color from the first emission stack.

The third light-emitting unit can include the second emission stack, a second charge generation layer and a third emission stack. The second charge generation layer can be disposed on the second emission stack. The third emission stack can be disposed on the second charge generation layer. A side surface of the second charge generation layer can be covered by the second emission stack between the first emission area and the third emission area.

The third emission stack can generate a light displaying a different color from the first emission stack and the second emission stack.

The second emission stack of the third light-emitting unit can be in contact with the second emission stack of the first light-emitting unit between the first emission area and the third emission area.

The third emission area can realize a same color as the second emission area.

In another aspect, a display apparatus comprises a device substrate including a first emission area and a second emission area. The second emission area is disposed side by side the first emission area. A first light-emitting device and a second light-emitting device are disposed on the device substrate. The first light-emitting device overlaps the first emission area. The first light-emitting device includes a first electrode, a first emission stack, a first charge generation layer, a second emission stack and a second electrode. The first emission stack is disposed on the first electrode. The first charge generation layer is disposed on the first emission stack. The second emission stack is disposed on the first charge generation layer. The second electrode is disposed on the second emission stack. The second light-emitting device overlaps the second emission area. The second light-emitting device includes the first electrode, the second emission stack, a second charge generation layer, a third emission stack and the second electrode. The second charge generation layer is disposed between the second emission stack and the second electrode. The third emission stack is disposed between the second charge generation layer and the second electrode. The second emission stack extends between the first charge generation layer and the second charge generation layer.

The second emission stack can include a portion overlapping the first emission area and a portion overlapping the second emission area. A portion of the second emission stack overlapping the second emission area can be disposed closer to the device substrate than a portion of the second emission stack overlapping the first emission area.

A planarization layer can be disposed between the device substrate and the first light-emitting device. The planarization layer can extend between the device substrate and the second light-emitting device. A third light-emitting device can be disposed on the planarization layer of a third emission area. The third emission area can be disposed side by side with the second emission area in a first direction. The second emission area can be disposed side by side with the first emission area in a second direction perpendicular to the first direction. The third light-emitting device can have a stacked structure of the first electrode, the second emission stack, the second charge generation layer, the third emission stack and the second electrode. The planarization layer can include a separation trench disposed between the second emission area and the third emission area. The second charge generation layer can be separated by the separation trench. A side surface of the second charge generation layer can be covered by the second emission stack between the first emission area and the second emission area.

The second emission area can realize a different color from the first emission area. The third emission area can realize a different color from the first emission area and the second emission area.

A fourth light-emitting device can be disposed on the planarization layer of a fourth emission area. The fourth emission area can be disposed side by side with the first emission area in the second direction. The third emission area can be disposed side by side with the fourth emission area in the first direction. The fourth light-emitting device can have a stacked structure of the first electrode, the first emission stack, the first charge generation layer, the second emission stack and the second electrode. The first charge generation layer can be separated between the first emission area and the fourth emission area by the separation trench. A side surface of the first charge generation layer can be covered by the second emission area between the third emission area and the fourth emission area.

The fourth emission area can realize a same color as the second emission area.

The second emission stack of the fourth emission area can be in contact with the second emission stack of the third emission area between the third emission area and the fourth emission area.

In another embodiment, there is provided a method of forming a display apparatus, comprising: disposing a device substrate including a first emission area, a second emission area, a third emission area, and a fourth emission area, wherein the third emission area is disposed side by side with the second emission area in a first direction, the second emission area is disposed side by side with the first emission area in a second direction perpendicular to the first direction, the fourth emission area is disposed side by side with the first emission area in the first direction, and the third emission area is disposed side by side with the fourth emission area in the second direction; forming a planarization layer on the device substrate, the planarization layer overlapping the first emission area, the second emission area, the third emission area, and the fourth emission area, wherein the planarization layer includes separation trenches respectively disposed between the first emission area and the fourth emission area, and/or between the second emission area and the third emission area; forming a first emission stack and a first charge generation layer over the first emission area and the fourth emission area; simultaneously forming a second emission stack over the first emission area, the second emission area, the third emission area, and the fourth emission area; and forming a second charge generation layer and a third emission stack on a portion of the second emission stack that overlap the second emission area and a portion of the second emission stack that overlap the third emission area, respectively.

In another embodiment, there is provided a display panel, comprising: a device substrate, wherein for each pixel, the device substrate comprises a first emission area, a second emission area, a third emission area, and a fourth emission area, arranged in a 2×2 matrix along a row direction and a column direction perpendicular to the row direction; a light-emitting device in each emission area; and a planarization layer extending between the light-emitting devices and the device substrate, wherein the light-emitting devices in the first row of the 2×2 matrix each include a first electrode, a first emission stack disposed on the first electrode, a first charge generation layer disposed on the first emission stack, a second emission stack disposed on the first charge generation layer, and a second electrode disposed on the second emission stack; wherein the light-emitting devices in the second row of the 2×2 matrix each include the first electrode, the second emission stack disposed on the first electrode, a second charge generation layer disposed on the second emission stack, a third emission stack disposed on the second charge generation layer, and the second electrode disposed on the third emission stack; wherein the first charge generation layers of the light-emitting devices are separated by separation trenches formed at least partially in the planarization layer between corresponding emission areas, and the second emission stack extends between the first charge generation layer and the second charge generation layer.

In another embodiment, there is provided a head mounted display apparatus, comprising an image element, the image element comprising a display apparatus according to any one of the above embodiments, and the image element being fixed in front of a user's eyes.

It is to be understood that both the foregoing general description and the following detailed description of the present disclosure are by way of example and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain various principles of the present disclosure. In the drawings:

FIG. 1 is a view schematically showing a display apparatus according to an example embodiment of the present disclosure;

FIG. 2 is an enlarged view of K region in FIG. 1;

FIG. 3 is a view showing a circuit of a sub-pixel in the display apparatus according an example embodiment of the present disclosure;

FIG. 4 is a cross-sectional view taken along line I-I′ in FIG. 2;

FIG. 5 is an enlarged view of R1 region in FIG. 4;

FIG. 6 is a cross-sectional view taken along line II-II′ in FIG. 2;

FIG. 7 is an enlarged view of R2 region in FIG. 6;

FIGS. 8 to 13 are views showing a method of forming the display apparatus according to an example embodiment of the present disclosure; and

FIGS. 14 to 17 are views showing the display apparatus according to another example embodiment of the present disclosure.

### DETAILED DESCRIPTION

Hereinafter, details related to the above objects, technical configurations, and operational effects of example embodiments of the present disclosure can be clearly understood based on the following detailed description with reference to the drawings, which illustrate some example embodiments of the present disclosure. Here, the example embodiments of the present disclosure are provided to allow those skilled in the art to sufficiently understand the technical sprit of the present disclosure, and thus the present disclosure may be embodied in other forms and is not limited to the example embodiments described below.

In addition, the same or extremely similar elements may be designated by the same reference numerals throughout the specification and in the drawings, and the lengths, thicknesses, and other dimensions of elements, layers, and regions may be exaggerated for convenience. It should be understood that, where a first element is referred to as being “on” a second element, the first element may be disposed on the second element so as to come into contact with the second element, or a third element may be interposed between the first element and the second element.

Here, such terms as, for example, “first” and “second” may be used to refer to any one element separately from another element. However, the first element and the second element may be arbitrary named according to the convenience of those skilled in the art without departing the technical sprit of the present disclosure.

The terms used in the specification of the present disclosure are merely used to describe particular example embodiments and are not intended to limit the scope of the present disclosure. For example, an element described in the singular form is intended to include a plurality of elements, and vice versa, unless the context clearly indicates otherwise. In addition, in the specification of the present disclosure, it should be further understood that the terms “comprise(s)” and “include(s)” specify the presence of stated features, integers, steps, operations, elements, components, and/or combinations thereof, but do not preclude the presence or addition of one or more other features, integers, steps, operations, elements, components, and/or combinations.

And, unless a more specific term like “directly” is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It should be further understood that terms, such as those defined in commonly used dictionaries, should be interpreted as having a meaning that is consistent with their meaning in the context of the relevant art and should not be interpreted in an idealized or overly formal sense unless expressly so defined herein.

### Example Embodiments

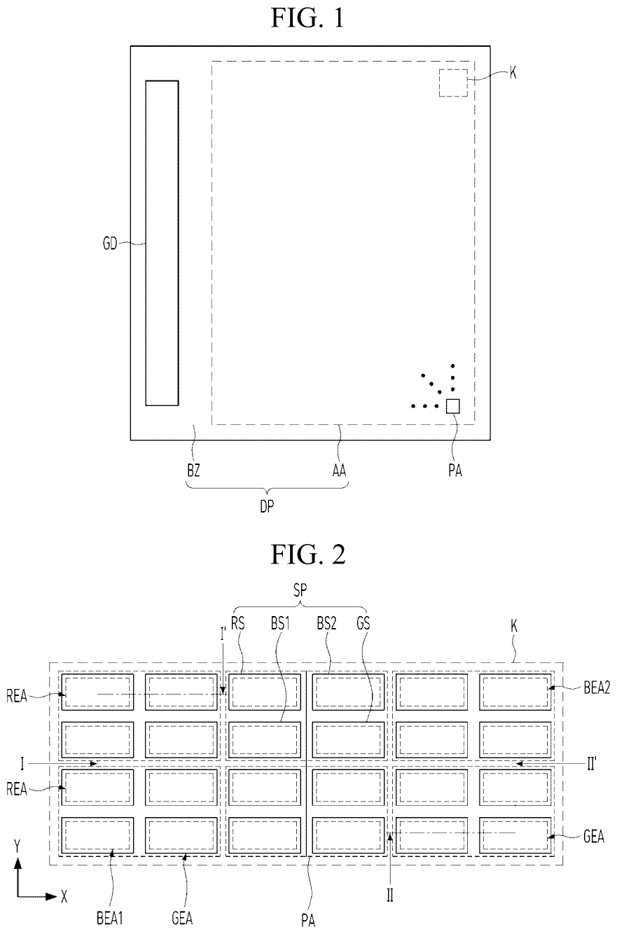

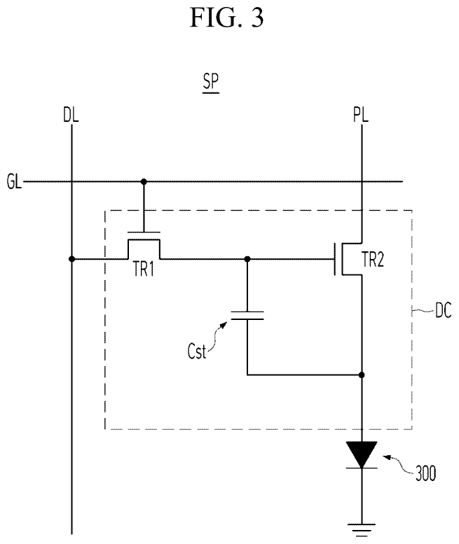

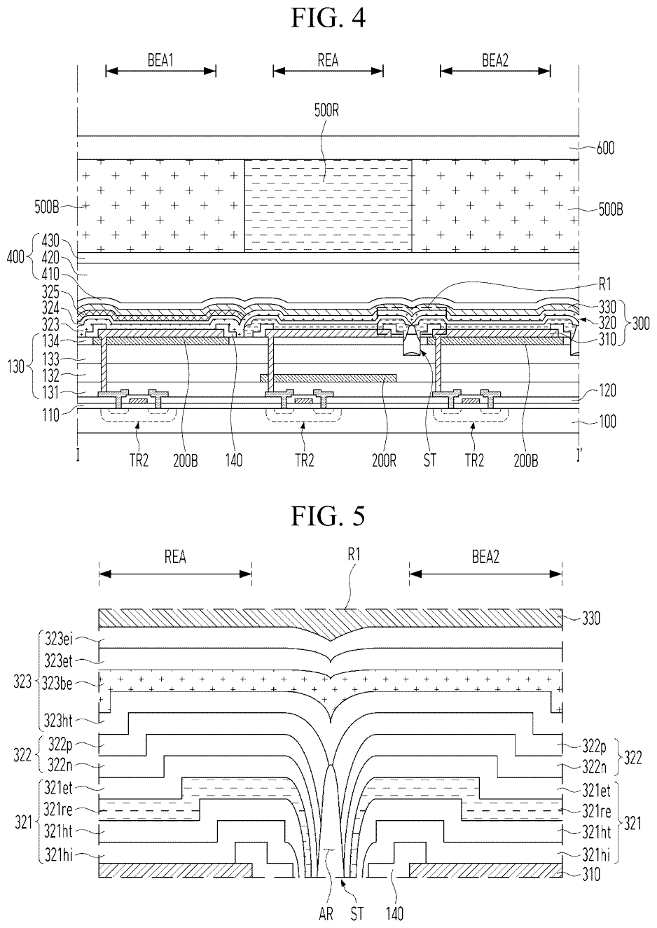

FIG. 1 is a view schematically showing a display apparatus according to an example embodiment of the present disclosure. FIG. 2 is an enlarged view of K region in FIG. 1. FIG. 3 is a view showing a circuit of a sub-pixel in the display apparatus according to an example embodiment of the present disclosure.

As shown in FIGS. 1 to 3, the display apparatus according to an example embodiment of the present disclosure can include a display panel DP. The display panel DP can generate an image provided to a user. For example, the display panel DP can include pixel areas PA. The pixel areas PA can be disposed side by side in a first direction X and a second direction Y. The second direction Y can be a direction perpendicular to the first direction X.

Each of the pixel areas PA can realize various colors. For example, each of the pixel areas PA can include sub-pixels SP. Each of the sub-pixels SP can display a specific color. For example, each of the sub-pixel SP can be one of a red sub-pixel RS displaying a red color, a blue sub-pixel BS1 and BS2 displaying a blue color, and a green sub-pixel GS displaying a green color. Each of the pixel areas PA can include four sub-pixel SP disposed side by side in the first direction X and the second direction Y. For example, each of the pixel areas PA can include the red sub-pixel RS, a first blue sub-pixel BS1 disposed side by side with the red sub-pixel RS in the second direction Y, the green sub-pixel GS disposed side by side with the first blue sub-pixel BS1 in the first direction, and a second blue sub-pixel BS2 disposed side by side with the green sub-pixel GS in the second direction Y. The second blue sub-pixel BS2 of each pixel area PA can be disposed side by side with the red sub-pixel RS of the corresponding pixel area PA in the first direction X. For example, in the display apparatus according to an example embodiment of the present disclosure, the red sub-pixel RS can be defined as a first sub-pixel, the first blue sub-pixel BS1 can be defined as a second sub-pixel, the green sub-pixel GS can be defined as a third sub-pixel, and the second blue sub-pixel BS2 can be defined as a fourth sub-pixel. In the display apparatus according to another example embodiment of the present disclosure, the red sub-pixel RS can be defined as a first sub-pixel, the second blue sub-pixel BS2 can be defined as a second sub-pixel, the green sub-pixel GS can be defined as a third sub-pixel, and the first blue sub-pixel BS1 can be defined as a fourth sub-pixel.

Each of the sub-pixels SP can be controlled by a signal applied through signal wirings GL, DL and PL. For example, a driving circuit DC electrically connected to the signal wirings GL, DL and PL, and a light-emitting device 300 electrically connected to the driving circuit DC can be disposed in each sub-pixel SP. For example, in the display apparatus according to an example embodiment of the present disclosure, the light-emitting device 300 of the red sub-pixel RS can be defined as a first light-emitting device, the light-emitting device 300 of the first blue sub-pixel BS1 can be defined as a second light-emitting device, the light-emitting device 300 of the green sub-pixel GS can be defined as a third light-emitting device, and the light-emitting device 300 of the second blue sub-pixel BS2 can be defined as a fourth light-emitting device. In the display apparatus according to another example embodiment of the present disclosure, the light-emitting device 300 of the red sub-pixel RS can be defined as a first light-emitting device, the light-emitting device 300 of the second blue sub-pixel BS2 can be defined as a second light-emitting device, the light-emitting device 300 of the green sub-pixel GS can be defined as a third light-emitting device, and the light-emitting device 300 of the first blue sub-pixel BS1 can be defined as a fourth light-emitting device.

The signal wirings GL, DL and PL can include a gate line GL applying a gate signal, a data line DL applying a data signal and a power voltage supply line PL supplying a power voltage. For example, the driving circuit DC can provide a driving current corresponding to the data signal to the light-emitting device 300 according to the gate signal by using the power voltage. The driving current provided to the light-emitting device 300 by the driving circuit DC can be maintained for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The second thin film transistor TR2 can generate the driving current corresponding to the data signal by using the power voltage. For example, the second thin film transistor TR2 can function as a driving thin film transistor. An operation of the second thin film transistor TR2 can be maintained by the storage capacitor Cst for one frame. For example, the storage capacitor Cst can be electrically connected to the gate electrode and the source electrode of the second thin film transistor TR2.

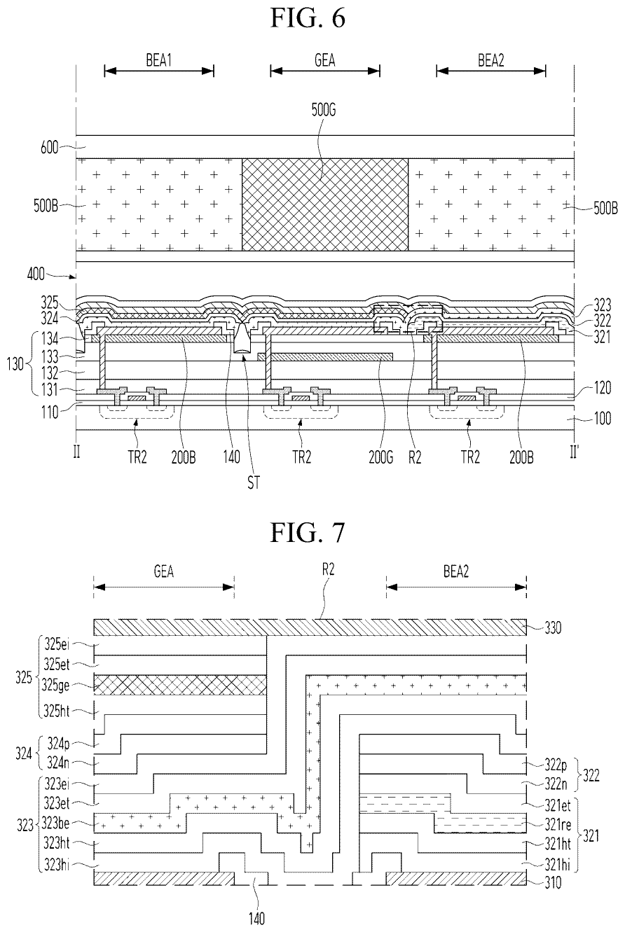

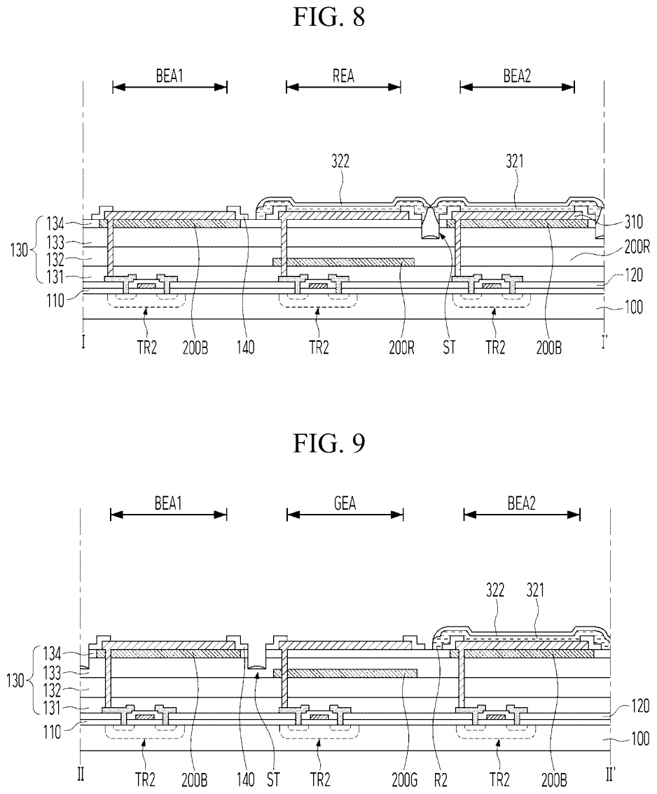

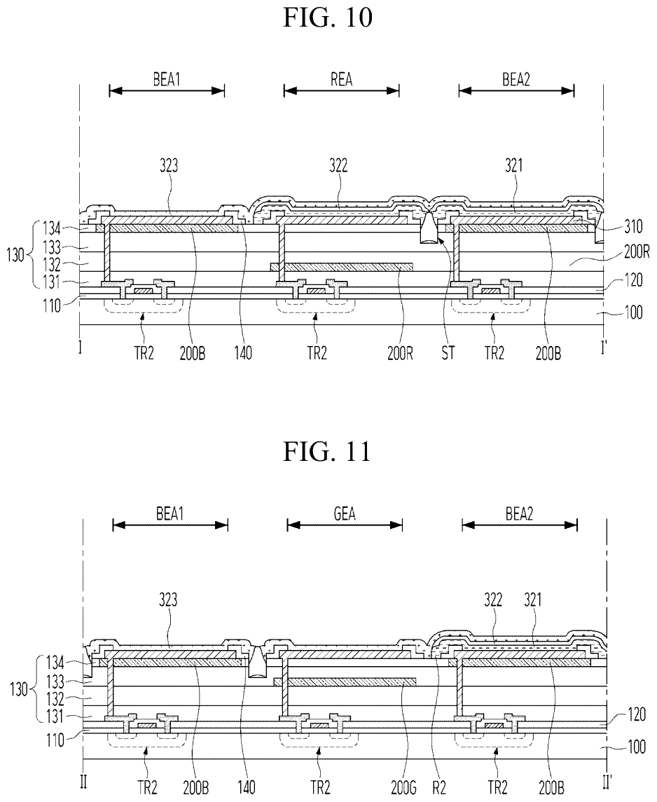

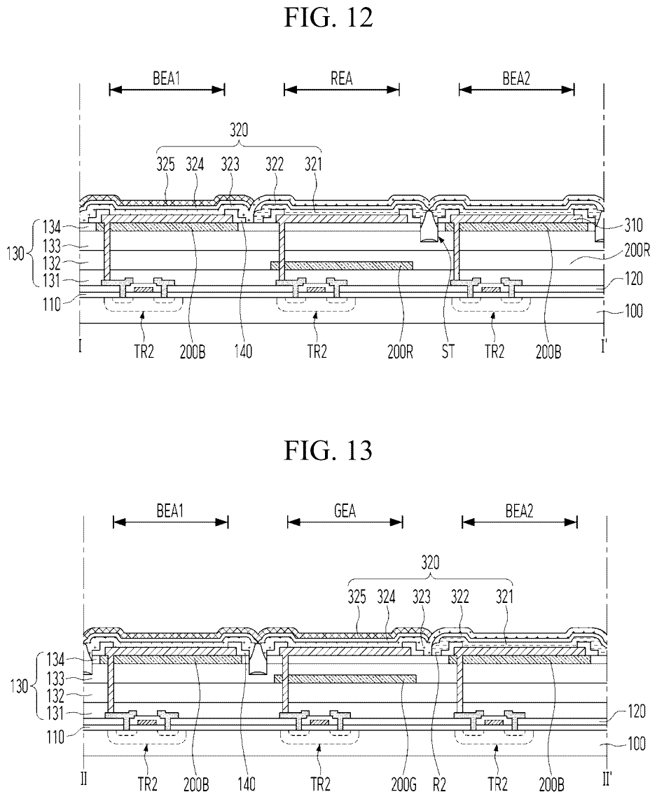

FIG. 4 is a cross-sectional view taken along line I-I′ in FIG. 2. FIG. 5 is an enlarged view of R1 region in FIG. 4. FIG. 6 is a cross-sectional view taken along line II-II′ in FIG. 2. FIG. 7 is an enlarged view of R2 region in FIG. 6.

As shown in FIGS. 1 to 7, the display apparatus according to an example embodiment of the present disclosure can include a device substrate 100 supporting the driving circuit DC of each sub-pixel SP. The device substrate 100 can include various materials. For example, the device substrate 100 can be a wafer made of a semiconductor material, such as silicon. The driving circuit of each sub-pixel SP can include a region disposed in the device substrate 100.

At least one of insulating layers 110, 120, 130 and 140 for preventing or suppressing unintended electrical connection can be disposed on the device substrate 100. For example, a gate insulating layer 110, an interlayer insulating layer 120, a planarization layer 130 and fences 140 can be disposed on the device substrate 100. The gate insulating layer 110 can be disposed on the device substrate 100. The interlayer insulating layer 120 can be disposed on the gate insulating layer 110. The planarization layer 130 can be disposed on the interlayer insulating layer 120. The planarization layer 130 can include a material having a higher fluidity than the gate insulating layer 110 and the interlayer insulating layer 120. For example, the gate insulating layer 110 and the interlayer insulating layer 120 can include an inorganic insulating material, and the planarization layer 130 can include an organic insulating material. The planarization layer 130 can be disposed on the driving circuit DC of each sub-pixel SP. A thickness difference due to the driving circuit DC of each sub-pixel SP can be removed by the planarization layer 130. For example, an upper surface of the planarization layer 130 opposite to the device substrate 100 can be flat.

The light-emitting device 300 of each sub-pixel SP can be disposed on the upper surface of the planarization layer 130. The light-emitting device 300 of each sub-pixel SP can emit light displaying a specific color. For example, the light-emitting device 300 of each sub-pixel SP can include a first electrode 310, a light-emitting unit 320 and a second electrode 330, which are sequentially stacked on the planarization layer 130 of the corresponding sub-pixel SP. For example, in the display apparatus according to an example embodiment of the present disclosure, the light-emitting unit 320 of the red sub-pixel RS can be defined as a first light-emitting unit, the light-emitting unit 320 of the first blue sub-pixel BS1 can be defined as a second light-emitting unit, the light-emitting unit 320 of the green sub-pixel GS can be defined as a third light-emitting unit, and the light-emitting unit 320 of the second blue sub-pixel BS2 can be defined as a fourth light-emitting unit. In the display apparatus according to another example embodiment of the present disclosure, the light-emitting unit 320 of the red sub-pixel RS can be defined as a first light-emitting unit, the light-emitting unit 320 of the second blue sub-pixel BS2 can be defined as a second light-emitting unit, the light-emitting unit 320 of the green sub-pixel GS can be defined as a third light-emitting unit, and the light-emitting unit 320 of the first blue sub-pixel BS1 can be defined as a fourth light-emitting unit.

The first electrode 310 and the second electrode 330 can include a conductive material. The second electrode 330 can include a different material from the first electrode 310. For example, the first electrode 310 can be a transparent electrode made of a transparent conductive material, such ITO and IZO, the second electrode 330 can be a translucent electrode in which a metal, such as silver (Ag) and magnesium (Mg), is thinly formed. The first electrode 310 of each sub-pixel SP can be electrically connected to the driving circuit DC of the corresponding sub-pixel SP. For example, the first electrode 310 of each sub-pixel SP can be in direct contact with the upper surface of the planarization layer 130.

The fences 140 can be disposed on the planarization layer 130. The first electrode 310 of each sub-pixel SP can be partially exposed by the fences 140. For example, the fences 140 can cover an edge of the first electrode 310 in each sub-pixel SP. The fences 140 can include an insulating material. Thus, in the display apparatus according to an example embodiment of the present disclosure, the first electrode 310 of each sub-pixel SP can be insulated from the first electrode 310 of adjacent sub-pixel SP by the fences 140.

The light-emitting unit 320 of each sub-pixel SP can generate light having luminance corresponding to a voltage difference between the first electrode 310 and the second electrode 330 of the corresponding sub-pixel SP. For example, the light-emitting unit 320 of each sub-pixel SP can be in direct contact with a portion of the first electrode 310 exposed by the fences 140 and the second electrode 330 in the corresponding sub-pixel SP. That is, in the display apparatus according to an example embodiment of the present disclosure, the fences 140 can define an emission area REA, BEA1, GEA and BEA2 in each sub-pixel SP. For example, in the display apparatus according to an example embodiment of the present disclosure, a red emission area REA of the red sub-pixel RS can be defined as a first emission area, a first blue emission area BEA1 of the first blue sub-pixel BS1 can be defined as a second emission area, a green emission area GEA of the green sub-pixel GS can be defined as a third emission area, and a second blue emission area BEA2 of the second blue sub-pixel BS2 can be defined as a fourth emission area. In the display apparatus according to another example embodiment of the present disclosure, the red emission area REA of the red sub-pixel RS can be defined as a first emission area, the second blue emission area BEA2 of the second blue sub-pixel BS2 can be defined as a second emission area, a green emission area GEA of the green sub-pixel GS can be defined as a third emission area, and a first blue emission area BEA1 of the first blue sub-pixel BS1 can be defined as a fourth emission area. For example, in the display apparatus according to an example embodiment of the present disclosure, the fences 140 can be disposed within a non-emission area.

The light-emitting unit 320 of each sub-pixel SP can include two emission stacks 321, 323 and 325 and a charge generation layer 322 and 324. The charge generation layer 322 can be disposed between two emission stacks 321 and 323 (as shown in the example of FIG. 5), and the charge generation layer 324 can be disposed between two emission stacks 323 and 325 (as shown in the example of FIG. 7). The light-emitting unit 320 of each sub-pixel SP can have a stacked structure same as the light-emitting unit 320 of the sub-pixel SP adjacent in the first direction X or the second direction Y. For example, in the display apparatus according to an example embodiment of the present disclosure, the light-emitting unit 320 on the red emission area REA of the red sub-pixel RS can have a stacked structure of a first emission stack 321, a first charge generation layer 322 and a second emission stack 323, the light-emitting unit 320 on a second blue emission area BEA2 of a second blue sub-pixel BS2 disposed side by side with the red emission area REA in the first direction X can have a stacked structure same as the light-emitting unit 320 of the light-emitting unit 320 on the red emission area REA. The light-emitting unit 320 of each sub-pixel SP can have a stacked structure different from the light-emitting unit 320 of the sub-pixel SP adjacent in the second direction Y or the first direction X. For example, in the display apparatus according to an example embodiment of the present disclosure, the light-emitting unit 320 on a first blue emission area BEA1 of a first blue sub-pixel BS1 disposed side by side with the red emission area REA in the second direction Y can have a stacked structure of the second emission stack 323, a second charge generation layer 324 and a third emission stack 325. The light-emitting unit 320 on a green emission area GEA of a green sub-pixel GS disposed side by side with the first blue emission area BEA1 in the first direction X can have a stacked structure same as the light-emitting unit 320 on the first blue emission area BEA1. That is, in the display apparatus according to an example embodiment of the present disclosure, the light-emitting unit 320 on the emission area REA, BEA1, GEA and BEA2 of each sub-pixel SP can have a stacked structure of the first emission stack 321, the first charge generation layer 322 and the second emission stack 323, or a stacked structure of the second emission stack 323, the second charge generation layer 324 and the third emission stack 325.

The first charge generation layer 322 can supply electrons or holes to adjacent emission stack 321 and 323, and the second charge generation layer 324 can supply electrons or holes to adjacent emission stack 323 and 325. For example, each of the first charge generation layer 322 and the second charge generation layer 324 can have a stacked structure of a n-type charge generating layer 322n and a p-type charge generating layer 322p, and a stacked structure of a n-type charge generating layer 324n and a p-type charge generating layer 324p, respectively. Thus, in the display apparatus according to an example embodiment of the present disclosure, each of the first emission stack 321, the second emission stack 323 and the third emission stack 325 can generate light.

Light generated by the first emission stack 321, light generated by the second emission stack 323 and light generated by the third emission stack 325 can display different colors. For example, in the display apparatus according to an example embodiment of the present disclosure, the first emission stack 321 can include a first hole injection layer 321hi, a first hole transport layer 321ht, a red emission material layer 321re and a first electron transport layer 321et, which are sequentially stacked, the second emission stack 323 can include a second hole injection layer 323hi, a second hole transport layer 323ht, a blue emission material layer 323be, a second electron transport layer 323et and a first electron injection layer 323ei, which are sequentially stacked, and the third emission stack 325 can include a third hole transport layer 325ht, a green emission material layer 325ge, a third electron transport layer 325et and a second electron injection layer 325ei, which are sequentially stacked. Thus, in the display apparatus according to an example embodiment of the present disclosure, the light-emitting unit 320 on the red emission area REA and the second blue emission area BEA2 can emit light in which the light generated by the red emission material layer 321re and the light generated by the blue emission material layer 323be are mixed, and the light-emitting unit 320 on the first blue emission area BEA1 and the green emission area GEA can emit light in which the light generated by the blue emission material layer 323be and the light generated by the green emission material layer 323ge are mixed.

A micro-cavity structure to emit light of a specific wavelength can be formed within the emission area REA, BEA1, GEA and BEA2 of each sub-pixel SP. For example, a reflective electrode 200R, 200B and 200G can be disposed between the driving circuit DC (for example, including a transistor TR2) and the first electrode 310 of each sub-pixel SP. A color displayed by the light emitted from the emission area REA, BEA1, GEA and BEA2 of each sub-pixel SP can be determined by the location of the reflective electrode 200R, 200B and 200G on the corresponding sub-pixel SP. For example, in the display apparatus according to an example embodiment of the present disclosure, the planarization layer 130 can have a stacked structure of a first planarization layer 131, a second planarization layer 132, a third planarization layer 133 and a fourth planarization layer 134, a red reflective electrode 200R of the red emission area REA can be disposed between the first planarization layer 131 and the second planarization layer 132, a blue reflective electrode 200B of the first blue emission area BEA1 and the second blue emission area BEA2 can be disposed on the third planarization layer 133, and a green reflective electrode 200G of the green emission area GEA can be disposed between the second planarization layer 132 and the third planarization layer 133. An upper surface of the blue reflective electrode 200B opposite to the device substrate 100 can be exposed by the fourth planarization layer 134. For example, the fourth planarization layer 134 can surround a side surface of the blue reflective electrode 200B. The blue reflective electrode 200B can be in direct contact with the first electrode 310 of the first blue emission area BEA1 or the second blue emission area BEA2. Thus, in the display apparatus according to an example embodiment of the present disclosure, red light can be emitted through the second electrode 330 of each red emission area REA, blue light can be emitted through the second electrode 330 of each of the first blue emission areas BEA1 and the second blue emission areas BEA2, and green light emitted through the second electrode 330 of each green emission area GEA.

A separating trench ST can be disposed between the fences 140. The separating trench ST can have a groove shape in which a portion of the planarization layer 130 is removed. For example, the separating trench ST can penetrate the fourth planarization layer 134 and a portion of the third planarization layer 133. The separating trench ST can extend in the second direction Y. The first charge generation layer 322 and the second charge generation layer 324 can be separated by the separating trench ST between the emission areas REA, BEA1, GEA and BEA2 adjacent in the first direction X. For example, in the display apparatus according to an example embodiment of the present disclosure, the first charge generation layer 322 can be separated by the separating trench ST between the red emission area REA and the second blue emission area BEA2, and the second charge generation layer 324 can be separated by the separating trench ST between the first blue emission area BEA1 and the green emission area GEA. Thus, in the display apparatus according to an example embodiment of the present disclosure, leakage current in the first direction X due to the first charge generation layer 322 and the second charge generation layer 324 can be prevented or suppressed.

The first emission stack 321 or the second emission stack 323 of each emission area REA, BEA1, GEA and BEA2 disposed relatively close to the device substrate 100 can be separated from the first emission stack 321 or the second emission stack 323 of the emission areas REA, BEA1, GEA and BEA2 adjacent in the first direction X by the separating trench ST. For example, in the display apparatus according to an example embodiment of the present disclosure, the first emission stack 321 of each second blue emission area BEA2 can be separated from the first emission stack 321 of adjacent red emission area REA by the separating trench ST, and the second emission stack 323 of each green emission area GEA can be separated from the second emission stack 323 of adjacent first blue emission area BEA1 by the separating trench ST. Thus, in the display apparatus according to an example embodiment of the present disclosure, an air-gap AR can be formed inside the separating trench ST.

The second emission stack 323 of the first blue emission area BEA1 and the green emission area GEA can be disposed closer to the device substrate 100 than the second emission stack 323 of the red emission area REA and the second blue emission area BEA2. The second emission stack 323 can extend in the second direction Y. For example, the second emission stack 323 of the first blue emission area BEA1 can be in direct contact with the second emission stack 323 of the red emission area REA between the red emission area REA and the first blue emission area BEA1, and the second emission stack 323 of the green emission area GEA can be in direct contact with the second emission stack 323 of the second blue emission area BEA2 between the second blue emission area BEA2 and the green emission area GEA. The second charge generation layer 324 can be spaced apart from the first charge generation layer 322. For example, the second emission stack 323 can extend between the first charge generation layer 322 and the second charge generation layer 324. The second charge generation layer 324 can be insulated from the first charge generation layer 322 by the second emission stack 323. For example, a side surface of the first charge generation layer 322 which extends in the first direction X and a side surface of the second charge generation layer 324 which extends in the first direction X can be covered by the second emission stack 323. That is, in the display apparatus according to an example embodiment of the present disclosure, a side surface of the first charge generation layer 322 and a side surface of the second charge generation layer 324, which are disposed between the red emission area REA and the first blue emission area BEA1 of each pixel area PA and between the second blue emission area BEA2 and the green emission area GEA of each pixel area PA can be covered by the second emission stack 323 of the corresponding pixel area PA. For example, in the display apparatus according to an example embodiment of the present disclosure, the second emission stack 323 can be in direct contact with the side surface of the first charge generation layer 322 which extends in the first direction X and the side surface of the second charge generation layer 324, which extends in the first direction X, thereby separating the side surface of the first charge generation layer 322 and the side surface of the second charge generation layer 324 in the second direction Y, as shown in FIGS. 4 and 6. Thus, in the display apparatus according to an example embodiment of the present disclosure, leakage current in the second direction Y due to the first charge generation layer 322 and the second charge generation layer 324 can be prevented or suppressed.

A signal applied to the second electrode 330 of each sub-pixel SP can be a same as signal applied to the second electrode 330 of adjacent sub-pixel SP. For example, the second electrode 330 of each sub-pixel SP can be electrically connected to the second electrode 330 of adjacent sub-pixel SP. Thus, in the display apparatus according to an example embodiment of the present disclosure, the luminance of the light emitted from the emission area REA, BEA1, GEA and BEA2 of each sub-pixel SP can be determined by the data signal applied to the driving circuit of the corresponding sub-pixel SP.

An encapsulation structure 400 can be disposed on the light-emitting device 300 of each sub-pixel SP. The encapsulation structure 400 can prevent or suppress the damage of the light-emitting device 300 in each sub-pixel SP due to the external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The second encapsulating layer 420 can include a material having a higher fluidity than the first encapsulating layer 410 and the third encapsulating layer 430. For example, the first encapsulating layer 410 and the third encapsulating layer 430 can include an inorganic insulating material, and the second encapsulating layer 420 can include an organic insulating material. A thickness difference due to the light-emitting device 300 of each sub-pixel SP can be removed by the second encapsulating layer 420. For example, an upper surface of the encapsulation structure 400 opposite to the device substrate 100 can be flat.

Color filters 500R, 500G and 500B can be disposed on the encapsulation structure 400. Each of the color filters 500R, 500G and 500B can overlap the emission area REA, GEA, BEA1 and BEA2 of one of the sub-pixels SP. Each of the color filters 500R, 500G and 500B can include a different material from adjacent color filter 500R, 500G and 500B. The light passing through the color filter 500R, 500G and 500B of each sub-pixel SP can display a same color as the light emitted by the micro-cavity structure formed in the corresponding sub-pixel SP. For example, the color filters 500R, 500G and 500B can include a red color filter 500R overlapping the red emission area REA, a blue color filter 500B overlapping the first blue emission area REA1 or the second blue emission area BEA2, and a green color filter 500G overlapping the green emission area GEA. Thus, in the display apparatus according to an example embodiment of the present disclosure, color reproducibility of each sub-pixel SP can be improved.

The color filters 500R, 500G and 500B can be disposed side by side from each other The color filter 500R, 500G and 500B of each sub-pixel SP can have a larger size than the emission area REA, BEA1, GEA and BEA2 of the corresponding sub-pixel SP. For example, a side surface of the color filters 500R, 500G and 500B can be in direct contact with a side surface of adjacent color filter 500R, 500G and 500B on the non-emission area. Thus, in the display apparatus according to an example embodiment of the present disclosure, light leakage from which light that does not pass through the color filters 500R, 500G and 500B is emitted can be prevented or suppressed. Therefore, in the display apparatus according to an example embodiment of the present disclosure, the quality of the image recognized by the user can be improved.

An optical planarization layer 600 can be disposed on the color filters 500R, 500G and 500B. The optical planarization layer 600 can prevent or suppress the damage of the color filters 500R, 500G and 500B due to the external impact and moisture. The optical planarization layer 600 can include an insulating material. For example, the optical planarization layer 600 can include an organic insulating material. A thickness difference due to the color filters 500R, 500G and 500B can be removed by the optical planarization layer 600. For example, an upper surface of the optical planarization layer 600 opposite to the device substrate 100 can be flat.

Accordingly, the display apparatus according to an example embodiment of the present disclosure can comprise the planarization layer 130 on the device substrate 100 and the light-emitting devices 300 on the planarization layer 130 of the emission areas REA, GEA, BEA1 and BEA2, wherein the light-emitting unit 320 of each light-emitting device 300 can have a stacked structure of the first emission stack 321, the first charge generation layer 322 and the second emission stack 323 or a stacked structure of the second emission stack 323, the second charge generation layer 324 and the third emission stack 325, wherein the first charge generation layer 322 and the second charge generation layer 324 can be separated by the separating trench ST formed in the planarization layer 130 between the emission areas REA, GEA, BEA1 and BEA2 adjacent in the first direction X, and wherein the side surface of the first charge generation layer 322 extending in the first direction X and the side surface of the second charge generation layer 324 extending in the first direction X can be covered by the second emission stack 323. Thus, in the display apparatus according to an example embodiment of the present disclosure, the leakage current in the first direction X due to the first charge generation layer 322 and the second charge generation layer 324 can be prevented or suppressed by the separating trench ST, and the leakage current in the second direction Y due to the first charge generation layer 322 and the second charge generation layer 324 can be prevented or suppressed by the second emission stack 323. Therefore, in the display apparatus according to an example embodiment of the present disclosure, decrease in the quality of the image due to the leakage current can be minimized or reduced.

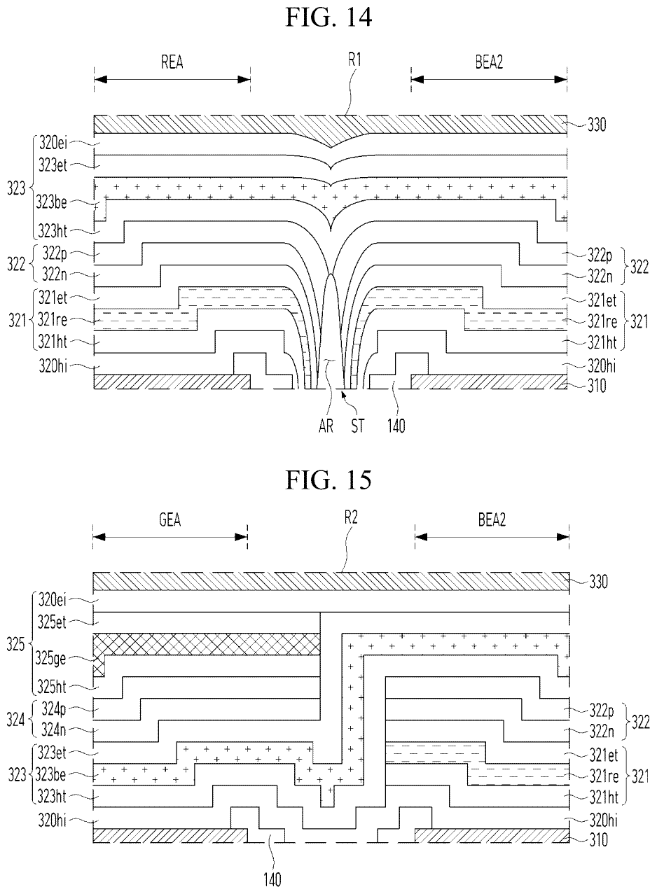

FIGS. 8 to 13 are views showing a method of forming the display apparatus according to an example embodiment of the present disclosure.

The method of forming the display apparatus according to an example embodiment of the present disclosure will be described with reference to FIGS. 2, 4, 6 and 8 to 13. First, as shown in FIGS. 2, 8 and 9, the method of forming the display apparatus according to an example embodiment of the present disclosure can include a step of forming the gate insulating layer 110, the interlayer insulating layer 120, the driving circuits DC, the planarization layer 130, the reflective electrodes 200R, 200G and 200B, the first electrodes 310 and the fences 140, and a step of forming the first emission stack 321 and the first charge generation layer 322 on the red emission area REA and the second blue emission area BEA2 of each pixel area PA.

Each of the driving circuits DC can include a second thin film transistor TR2. The planarization layer 130 can include the separating trench ST disposed between the red emission area REA and the second blue emission area BEA2 and between the first blue emission area BEA1 and the green emission area GEA of each pixel area PA.

The first emission stack 321 of the second blue emission area BEA2 can be formed simultaneously with the first emission stack 321 of the red emission area REA. The first charge generation layer 322 of the second blue emission area BEA2 can be formed simultaneously with the first charge generation layer 322 of the red emission area REA. For example, a step of forming the first emission stack 321 and the first charge generation layer 322 on the red emission area REA and the second blue emission area BEA2 of each pixel area PA can include a step of arranging a first mask pattern exposing the red emission area REA and the second blue emission area BEA2 of each pixel area PA on the device substrate 100 in which the fences 140 are formed, and a step of forming the first emission stack 321 and the first charge generation layer 322 using the first mask pattern.

The first mask pattern can be a fine metal mask (FMM). The first mask pattern cannot include a region overlapping the non-emission area disposed between the red emission area REA and the second blue emission area BEA2 of each pixel area PA. For example, the separating trench ST disposed between the red emission area REA and the second blue emission area BEA2 of each pixel area PA can be exposed by the first mask pattern. Thus, in the method of forming the display apparatus according to an example embodiment of the present disclosure, the first emission stack 321 of the second blue emission area BEA2 can be separated from the first emission stack 321 of the red emission area REA by the separating trench ST, and the first charge generation layer 322 of the second blue emission area BEA2 can be separated from the first charge generation layer 322 of the red emission area REA by the separating trench ST, without additional process. That is, in the method of forming the display apparatus according to an example embodiment of the present disclosure, the first emission stack 321 separated from adjacent first emission stack 321 can be formed simultaneously on the red emission area REA and the second blue emission area BEA2 which have a smaller size than an opening of the first mask pattern, and the first charge generation layer 322 separated from adjacent first charge generation layer 322 can be formed simultaneously on the first emission stack 321 on the red emission area REA or the second blue emission area BEA2. Therefore, in the method of forming the display apparatus according to an example embodiment of the present disclosure, the process efficiency and the resolution can be improved.

As shown in FIGS. 10 and 11, the method of forming the display apparatus according to an example embodiment of the present disclosure can include a step of forming the second emission stack 323 on the device substrate 100 in which the first emission stack 321 and the first charge generation layer 322 are formed.

The second emission stack 323 can be formed simultaneously on the red emission area REA, the first blue emission area BEA1, the green emission area GEA and the second blue emission area BEA2 of each pixel area PA. The second emission stack 323 can include a region disposed on the non-emission area. For example, in the method of forming the display apparatus according to an example embodiment of the present disclosure, the second emission stack 323 can be formed, without using a mask pattern. That is, in the method of forming the display apparatus according to an example embodiment of the present disclosure, a process of forming a mask pattern for a process of forming the second emission stack 323 can be omitted. Thus, in the method of forming the display apparatus according to an example embodiment of the present disclosure, the process efficiency can be improved. The first emission stack 321 and the first charge generation layer 322 formed on the red emission area REA and the second blue emission area BEA2 can be covered by the second emission stack 323. The side surface of the first emission stack 321 and the side surface of the first charge generation layer 322 which extend in the first direction X can be in direct contact with the second emission stack 323.

As shown in FIGS. 12 and 13, the method of forming the display apparatus according to an example embodiment of the present disclosure can include a step of forming the second charge generation layer 324 and the third emission stack 325 on a portion of the second emission stack 323 overlapping the first blue emission area BEA1 of each pixel area PA and a portion of the second emission stack 323 overlapping the green emission area GEA of each pixel area PA.

The second charge generation layer 324 of the green emission area GEA can be formed simultaneously with the second charge generation layer 324 of the first blue emission area BEA1. The third emission stack 325 of the green emission area GEA can be formed simultaneously with the third emission stack 325 of the first blue emission area BEA1. For example, a step of forming the second charge generation layer 324 and the third emission stack 325 can include a step of arranging a second mask pattern exposing the first blue emission area BEA1 and the green emission area GEA of each pixel area PA on the device substrate 100 in which the second emission stack 323 is formed, and a step of forming the second charge generation layer 324 and the third emission stack 325 using the second mask pattern.

The second mask pattern can be a fine metal mask (FMM). The second mask pattern cannot include a region overlapping the non-emission area between the first blue emission area BEA1 and the green emission area GEA of each pixel area PA. For example, the separating trench ST disposed between the first blue emission area BEA1 and the green emission area GEA of each pixel area PA can be exposed by the second mask pattern. Thus, in the method of forming the display apparatus according to an example embodiment of the present disclosure, the second charge generation layer 324 of the green emission area GEA can be separated from the second charge generation layer 324 of the first blue emission area BEA1 by the separating trench ST, and the third emission stack 325 of the green emission area GEA can be separated from the third emission stack 325 of the first blue emission area BEA1 by the separating trench ST, without additional process. That is, in the method of forming the display apparatus according to an example embodiment of the present disclosure, the second charge generation layer 324 separated from adjacent the second charge generation layer 324 can be formed simultaneously on the first blue emission area BEA1 and the green emission area GEA which have a smaller size than an opening of the second mask pattern, and the third emission stack 325 separated from adjacent third emission stack 325 can be formed simultaneously on the second charge generation layer 324 on the first blue emission area BEA1 or the green emission area GEA. Therefore, in the method of forming the display apparatus according to an example embodiment of the present disclosure, the process efficiency and the resolution can be improved.

AS shown in FIGS. 4 and 6, the method of forming the display apparatus according to an example embodiment of the present disclosure can include a step of forming the second electrode 330 on the light-emitting unit 320 composed of the first emission stack 321, the first charge generation layer 322, the second emission stack 323, the second charge generation layer 324 and the third emission stack 325 to form the light-emitting device 300, a step of forming the encapsulation structure 400 on the second electrode 330, a step of forming the color filters 500R, 500G and 500B on the encapsulation structure 400 and a step of forming the optical planarization layer 600 on the color filters 500R, 500G and 500B.

Accordingly, in the method of forming the display apparatus according to an example embodiment of the present disclosure, the second emission stack 323 of each sub-pixel SP can be formed simultaneously. Thus, in the method of forming the display apparatus according to an example embodiment of the present disclosure, the process efficiency can be improved. That is, in the method of forming the display apparatus according to an example embodiment of the present disclosure, production energy can be reduced by process optimization. And, in the method of forming the display apparatus according to an example embodiment of the present disclosure, each of the emission areas REA, BEA1, GEA and BEA2 can have a smaller size than an opening of the first mask pattern and an opening of the second mask pattern. Therefore, in the method of forming the display apparatus according to an example embodiment of the present disclosure, the resolution can be improved.

As shown in FIG. 1, in the display apparatus according to an example embodiment of the present disclosure, the display panel DP can include a display area AA and a bezel area BZ disposed outside the display area AA. The pixel areas PA can be disposed within the display area AA. For example, the display area AA can be surrounded by the bezel area BZ. A gate driver GD electrically connected to the gate line GL, a data driver electrically connected to the data line DL and a power unit electrically connected to the power voltage supply line PL can be disposed outside the display area AA. At least one of the gate driver GD, the data driver and the power unit can be disposed on the bezel area BZ. For example, the display apparatus according to an example embodiment of the present disclosure can be a GIP (Gate-In-Panel) type display apparatus in which the gate driver GD can be formed in the bezel area BZ.

The display apparatus according to an example embodiment of the present disclosure is described that the driving circuit DC of each sub-pixel SP consists of the first thin film transistor TR1, the second thin film transistor TR2 and the storage capacitor Cst. However, in the display apparatus according to another example embodiment of the present disclosure, the driving circuit DC of each sub-pixel SP can include a plurality of switching thin film transistors. For example, in the display apparatus according to another example embodiment of the present disclosure, the driving circuit DC of each sub-pixel SP can further include a third thin film transistor to initialize the storage capacitor Cst of the corresponding sub-pixel SP according to the gate signal. Thus, in the display apparatus according to another example embodiment of the present disclosure, the degree of freedom in the configuration of each driving circuit DC can be improved.

The display apparatus according to an example embodiment of the present disclosure is described that the device substrate 100 is a wafer formed of a semiconductor material, such as silicon. However, in the display apparatus according to another example embodiment of the present disclosure, the device substrate 100 can include glass or plastic. The driving circuit DC of each sub-pixel SP can be formed on a buffer insulating layer covering an upper surface of the device substrate 100. Thus, in the display apparatus according to another example embodiment of the present disclosure, the degree of freedom in the material of the device substrate 100 and the configuration of each driving circuit DC can be improved.

The display apparatus according to an example embodiment of the present disclosure is described that the first emission stack 312 includes the red emission material layer 321re, the second emission stack 323 includes the blue emission material layer 323be, and the third emission stack 325 includes the green emission material layer 325ge. However, in the display apparatus according to another example embodiment of the present disclosure, the emission material layers 321re, 323be and 325ge of the first emission stack 321, the second emissions stack 323 and the third emission stack 325 can be combined in various ways. For example, in the display apparatus according to another example embodiment of the present disclosure, the first emission stack 321 can include the blue emission material layer 323be, the second emission stack 323 can include the green emission material layer 325ge, and the third emission stack 325 can include the red emission material layer 321re. Alternately, in the display apparatus according to another example embodiment of the present disclosure, the first emission stack 321 can include the green emission material layer 325ge, the second emission stack 323 can include the red emission material layer 321re, and the third emission stack 325 can include the blue emission material layer 323be. Thus, in the display apparatus according to another example embodiment of the present disclosure, the degree of freedom in the configuration of the light-emitting unit 320 on each sub-pixel SP can be improved.

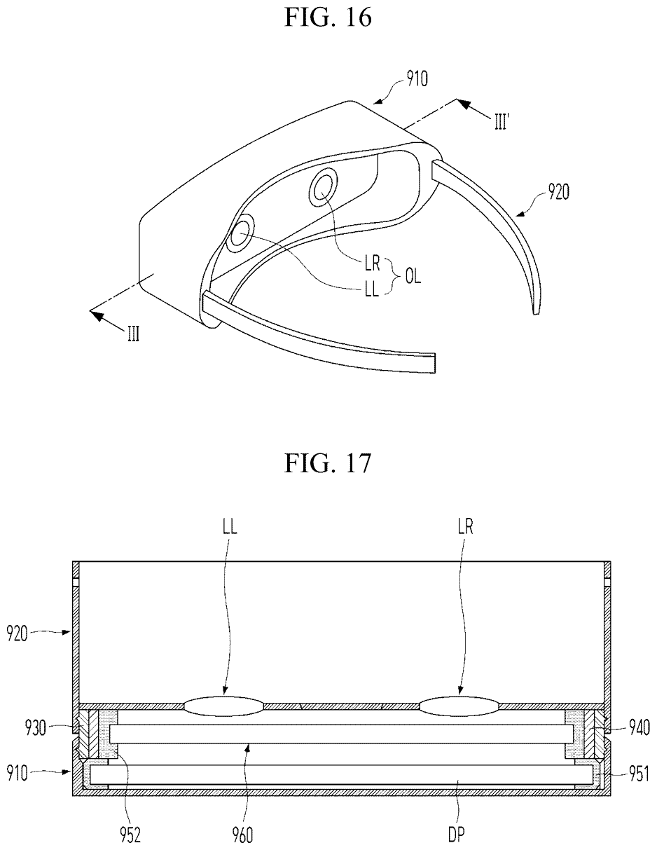

The display apparatus according to an example embodiment of the present disclosure is described that the first hole injection layer 321hi of the first emission stack 321 can be separated by the separating trench ST. However, in the display apparatus according to another example embodiment of the present disclosure, a hole injection layer that is in contact with the first electrode 310 can be formed simultaneously on the emission areas REA, BEA1, GEA and BEA2 of each sub-pixel SP. For example, in the display apparatus according to another example embodiment of the present disclosure, a common hole injection layer 320hi can be disposed on the first electrode 310 of each sub-pixel SP, the first emission stack 321 of the red emission area REA and the second blue emission area BEA2 can be include the first hole transport layer 321ht, the red emission material layer 321re and the first electron transport layer 321et, which are sequentially stacked on the common hole injection layer 320hi, and the second emission stack 323 of the first blue emission area BEA1 and the green emission area GEA can include the second hole transport layer 323ht, the blue emission area 323be and the second electron transport layer 323et, which are sequentially stacked on the common hole injection layer 320hi, as shown in FIGS. 14 and 15. Thus, in the display apparatus according to another example embodiment of the present disclosure, the process efficiency can be effectively improved.

The display apparatus according to an example embodiment of the present disclosure is described that the second electrode 330 is in direct contact with the first electron injection layer 323ei of the second emission stack 323 or the second electron injection layer 325ei of the third emission stack 325. However, in the display apparatus according to another example embodiment of the present disclosure, an electron injection layer that is in contact with the second electrode 330 can be formed simultaneously on the emission area REA, BEA1, GEA and BEA2 of each sub-pixel SP. For example, in the display apparatus according to another example embodiment of the present disclosure, an common electron injection layer 320ei can be formed on the red emission area REA, the first blue emission area BEA1, the green emission area GEA and the second blue emission area BEA2, and the second electrode 330 can be formed on the common electron injection layer 320ei, as shown in FIGS. 14 and 15.

The common electron injection layer 320ei can be in direct contact with the second electron transport layer 323et of the red emission area REA and the second blue emission area BEA2. The third electron transport layer 325et of the first blue emission area BEA1 and the green emission area GEA can be in direct contact with the common electron injection layer 320ei. Thus, in the display apparatus according to another example embodiment of the present disclosure, the process efficiency can be effectively improved.

In the display apparatus according to another example embodiment of the present disclosure, the display panel DP can be used in various electronic devices. For example, the display apparatus according to another example embodiment of the present disclosure can be a head mounted display apparats (HMD) in which the display panel DP is accommodated in an image element 910 and the image element 910 is fixed in front of the user's eyes by a mounting element 920, as shown in FIGS. 16 and 17. The mounting element 920 can have a shape, such as a leg of a spectacle frame. For example, the mounting element 920 can have a shape extending in a direction from an edge of the image element 910. The mounting element 920 can be coupled to the image element 910 by a coupling element 930. For example, the coupling element 930 can have a plate shape including a region coupled to the image element 910 and a region coupled to the mounting element 920. The coupling element 930 can be disposed inside the image element 910 and the mounting element 920.

Eyepiece lenses OL disposed on a side of the image element 910 can include a left-eye lens LL disposed in front of the user's left eye, and a right-eye lens LR disposed in front of the user's right eye. An empty space can be disposed between the display panel DP and the eyepiece lenses OL. For example, the display panel DP can be disposed close to a first surface of the image element 910, and the left-eye lens LL and the right-eye lens LR can be fixed at a second surface of the image element 910 opposite to the first surface of the image element 910. A gap maintaining element 940 can be disposed inside the coupling element 930 to maintain a space between the display panel DP and the eyepiece lenses OL. The gap maintaining element 940 can be disposed parallel to the coupling element 930. For example, the gap maintaining element 940 can be in direct contact with the coupling element 930.

A first fixing element 951 to fix the display panel DO can be disposed in the image element 910. For example, the first fixing element 951 can be in direct contact with the first surface of the image element 910. Thus, in the display apparatus according to another example embodiment of the present disclosure, the movement of the display panel DP and the eyepiece lenses OL according to the user's movement can be effectively prevented or suppressed. Therefore, in the display apparatus according to another example embodiment of the present disclosure, the visibility of the image recognized by the user can be improved.

In the display apparatus according to another example embodiment of the present disclosure, the image by the display panel DP and an actual object disposed beyond the first surface of the image element 910 can be provided simultaneously to the user. The first surface of the image element 910 can have a high transmittance. For example, at least one optical lens 960 can be disposed between the display panel DP and the eyepiece lenses OL. The at least one optical lens 960 can be spaced apart from the display panel DP and the eyepiece lens OL. For example, a second fixing element 952 to fix the at least one optical lens 960 can be disposed in the image element 910. The image by the display panel DP can be displayed on an actual object disposed in front of the user by the at least one optical lens 960. Thus, in the display apparatus according to another example embodiment of the present disclosure, an accident due to blocking the user's view can be prevented or suppressed.

The display apparatus according to another example embodiment of the present disclosure is described that the mounting element 920 has a shape, such as a leg of a spectacle frame. However, in the display apparatus according to another example embodiment of the present disclosure, the mounting element 920 can have various shapes. For example, in the display apparatus according to another example embodiment of the present disclosure, the mounting element 920 can have a head gear shape surrounding the user's head. Thus, in the display apparatus according to another example embodiment of the present disclosure, the degree of freedom in a type of the electronic devices in which the display panel DP is used can be improved.

In the result, the display apparatus according to example embodiments of the present disclosure can comprise the planarization layer and the light-emitting device on the device substrate, wherein the light-emitting unit of the light-emitting device can include the charge generation layer disposed between the first emission stack and the second emission stack, the charge generation layer can be separated by the separating trench of the planarization layer extending in the first direction, and wherein the side surface of the charge generation layer extending in the second direction perpendicular to the first direction can be covered by the first emission stack or the second emission stack. Thus, in the display apparatus according to example embodiments of the present disclosure, the leakage current in the first direction and the second direction due to the charge generation layer can be prevented or suppressed. Thereby, in the display apparatus according to example embodiments of the present disclosure, the decrease in the quality of the image due to the leakage current can be minimized or reduced. And, in the display apparatus according to example embodiments of the present disclosure, the production energy can be reduced by process optimization.

What is claimed is:

1. A display apparatus, comprising:
a device substrate including a first emission area, a second emission area, and a third emission area, the second emission area being disposed side by side with the first emission area in a first direction, and the third emission area being disposed side by side with the first emission area in a second direction perpendicular to the first direction;
a planarization layer on the device substrate, the planarization layer overlapping the first emission area, the second emission area, and the third emission area;
a first light-emitting device on the planarization layer of the first emission area, the first light-emitting device including a first light-emitting unit disposed between a first electrode and a second electrode;
a second light-emitting device on the planarization layer of the second emission area, the second light-emitting device including a second light-emitting unit disposed between the first electrode and the second electrode; and
a third light-emitting device on the planarization layer of the third emission area, the third light-emitting device including a third light-emitting unit disposed between the first electrode and the second electrode,
wherein each of the first light-emitting unit and the second light-emitting unit has a stacked structure of a first emission stack, a first charge generation layer, and a second emission stack,
wherein the planarization layer includes a separation trench separating the first charge generation layer between the first emission area and the second emission area, and
wherein a side surface of the first charge generation layer is covered by the second emission stack between the first emission area and the third emission area.

2. The display apparatus according to claim 1, wherein the second emission stack is in contact with the side surface of the first charge generation layer extending in the first direction.

3. The display apparatus according to claim 1, wherein the second emission area realizes a different color from the first emission area.

4. The display apparatus according to claim 3, wherein the second emission stack generates a light displaying a different color from the first emission stack.

5. The display apparatus according to claim 3, wherein the third light-emitting unit includes a second charge generation layer on the second emission stack and a third emission stack on the second charge generation layer, and
wherein a side surface of the second charge generation layer is covered by the second emission stack between the first emission area and the third emission area.

6. The display apparatus according to claim 5, wherein the third emission stack generates a light displaying a different color from the first emission stack and the second emission stack.

7. The display apparatus according to claim 5, wherein the second emission stack of the third light-emitting unit is in contact with the second emission stack of the first light-emitting unit between the first emission area and the third emission area.

8. The display apparatus according to claim 7, wherein the third emission area realizes a same color as the second emission area.

9. A display apparatus, comprising:
a device substrate including a first emission area and a second emission area, the second emission area being disposed side by side the first emission area;
a first light-emitting device on the first emission area of the device substrate, the first light-emitting device including a first electrode, a first emission stack on the first electrode, a first charge generation layer on the first emission stack, a second emission stack on the first charge generation layer, and a second electrode on the second emission stack; and
a second light-emitting device on the second emission area of the device substrate, the second light-emitting device including the second emission stack on the first electrode, a second charge generation layer on the second emission stack, a third emission stack on the second charge generation layer, and the second electrode on the third emission stack,
wherein the second emission stack extends between the first charge generation layer and the second charge generation layer.

10. The display apparatus according to claim 9, wherein a portion of the second emission stack overlapping the second emission area is disposed closer to the device substrate than a portion of the second emission stack overlapping the first emission area.

11. The display apparatus according to claim 9, further comprising:
a planarization layer between the device substrate and the first light-emitting device, the planarization layer extending between the device substrate and the second light-emitting device; and
a third light-emitting device on the planarization layer of a third emission area, the third light-emitting device having a stacked structure of the first electrode, the second emission stack, the second charge generation layer, the third emission stack and the second electrode,
wherein the third emission area is disposed side by side with the second emission area in a first direction,
wherein the second emission area is disposed side by side with the first emission area in a second direction perpendicular to the first direction,
wherein the planarization layer includes a separation trench separating the second charge generation layer between the second emission area and the third emission area, and
wherein a side surface of the second charge generation layer is covered by the second emission stack between the first emission area and the second emission area.

12. The display apparatus according to claim 11, wherein the second emission area realizes a different color from the first emission area, and the third emission area realizes a different color from the first emission area and the second emission area.

13. The display apparatus according to claim 11, further comprising a fourth light-emitting device on the planarization layer of a fourth emission area,
wherein the fourth light-emitting device has a stacked structure of the first electrode, the first emission stack, the first charge generation layer, the second emission stack and the second electrode,
wherein the fourth emission area is disposed side by side with the first emission area in the first direction,
wherein the third emission area is disposed side by side with the fourth emission area in the first direction,
wherein the first charge generation layer is separated between the first emission area and the fourth emission area by the separation trench, and
wherein a side surface of the first charge generation layer is covered by the second emission stack between the third emission area and the fourth emission area.

14. The display apparatus according to claim 13, wherein the fourth emission area realizes a same color as the second emission area.

15. The display apparatus according to claim 13, wherein the second emission stack of the fourth emission area is in contact with the second emission stack of the third emission area between the third emission area and the fourth emission area.
